(19) United States
(12) Patent Application Publication
(10) Pub. No.: US 2024/0387786 A1
(43) Pub. Date: Nov. 21, 2024

(54) DISPLAY PANELS AND DISPLAY DEVICES

(71) Applicant: Wuhan China Star Optoelectronics Semiconductor Display Technology Co., Ltd., Wuhan, Hubei (CN)

(72) Inventor: Shuyuan ZHANG, Wuhan, Hubei (CN)

(73) Assignee: Wuhan China Star Optoelectronics Semiconductor Display Technology Co., Ltd., Wuhan, Hubei (CN)

(21) Appl. No.: 18/269,771

(22) PCT Filed: Apr. 17, 2023
(86) PCT No.: PCT/CN2023/088562

§ 371 Date: Jun. 27, 2023

(30) Foreign Application Priority Data
Jun. 30, 2022 (CN) 202210778550.0

(51) Int. Cl. H01L 33/62; H01L 25/075; H01L 25/16

(52) U.S. Cl. CPC H01L 33/62; H01L 25/0753; H01L 25/167

(57) ABSTRACT

A display panel and a display device are provided. The display panel includes a functional area, a package area around the functional area, a display area around the functional area, and includes at least one winding lines disposed in the display area. The winding line includes a first linear section and a second linear section extending along a same direction and separated by the functional area and the package area, and includes a winding section connecting the first linear section and the second linear section. The first linear section and the second linear section are arranged in a same layer, and the winding section and the first linear section are arranged in different layers. A projection of the winding section in a thickness direction of the display panel falls within a projection of other metal layers of the display panel in the thickness direction.

### TECHNICAL FIELD

The present disclosure relates to the field of display technologies, and in particular, to display panels and display devices.

### BACKGROUND

In order to increase a screen-to-body ratio of a mobile electronic terminal (particular to a mobile phone), in related art, a hole-digging area is generally provided in the display screen, so that a functional element such as a camera is arranged in the display area. However, when the hole-digging area is arranged, a border area is generally required to accommodate a winding section of a data line and a package structure at an edge of the hole-digging area, resulting in a large area of the border area. In view of this, some technicians propose that the winding section of the data line can be arranged in the display area, so as to reduce the border area of the hole-digging area. However, when the winding section of the data line is arranged in the display area, there will be differences of a patterned structure of a metal layer where the data line is located in a position close to the hole-digging area and a position away from the hole-digging area in the display area, and the difference may cause mura display of the display panel.

### SUMMARY OF THE INVENTION

### Technical Problems

New display panels and display devices according to the present disclosure are provided to reduce a border area of a hole-cutting area and relieve the technical problem of mura display of the display panel.

### Technical Solutions

Technical solutions according to the present disclosure are provided as follows:

In a first aspect, the present disclosure provides a display panel, including a functional area, a package area around the functional area, a display area around the functional area, and including one or more winding lines disposed in the display area; herein, each of the winding lines includes a first linear section and a second linear section extending along a same direction and separated by the functional area and the package area, and includes a winding section connecting the first linear section and the second linear section; the first linear section and the second linear section are arranged in a same layer, and the winding section and the first linear section are arranged in different layers; and a projection of the winding section in a thickness direction of the display panel falls within a projection of other metal layers of the display panel in the thickness direction of the display panel.

In an embodiment, the display panel further includes: a substrate; a driving circuit layer disposed on a side of the substrate; a first metal layer disposed on a side of the driving circuit layer away from the substrate; and a second metal layer disposed on a side of the first metal layer away from the substrate; herein, the winding section is disposed in the first metal layer, and an orthographic projection of the winding section on the substrate falls within an orthographic projection of the driving circuit layer and an orthographic projection of the second metal layer on the substrate.

In an embodiment, the winding section includes at least one first connecting line extending along a first direction and at least one second connecting line extending along a second direction; two ends of the first connecting line and the second connecting line after connected in a head-to-tail way are connected to the first linear section and the second linear section, respectively; and an orthographic projection of the first connecting line on the substrate falls within an orthographic projection of the driving circuit layer on the substrate, and an orthographic projection of the second connecting line on the substrate falls within an orthographic projection of the second metal layer on the substrate.

In an embodiment, the display panel further includes a reset signal line, the reset signal line is disposed in the driving circuit layer, and an orthographic projection of the first connecting line on the substrate falls within an orthographic projection of the reset signal line on the substrate.

In an embodiment, the display panel further includes a power signal line, the power signal line is disposed in the second metal layer, and an orthographic projection of the second connecting line on the substrate falls within an orthographic projection of the power signal line on the substrate.

In an embodiment, the reset signal line includes a first reset signal line and a second reset signal line; in the display area, the display panel further includes a plurality of light-emitting devices and a plurality of driving thin film transistors disposed in the driving circuit layer; and the first reset signal line is electrically connected to gates of the driving thin film transistors, and the second reset signal line is electrically connected to anodes of the light-emitting devices.

In an embodiment, in the display area, the driving circuit layer includes the gates and a source and drain layer of the driving thin film transistors; the first reset signal line and the gates of the driving thin film transistors are disposed in a same layer; and the second reset signal line and the source and drain layer are disposed in a same layer.

In an embodiment, an orthographic projection of the first connecting line on the substrate falls within an orthographic projection of the first reset signal line on the substrate.

In an embodiment, in the display area, the display panel further includes a pixel definition layer including a first pixel definition layer and a second pixel definition layer stacked thereon; the first pixel definition layer is disposed on the anodes of the light-emitting devices, and the second pixel definition layer is black and disposed on a side of the first pixel definition layer away from the substrate; a plurality of pixel openings are defined on the pixel definition layer and run through the second pixel definition layer and a part of the first pixel definition layer to expose the anodes; and each of the light-emitting devices includes a light-emitting structure disposed in one of the pixel openings and on one of the anodes correspondingly.

In an embodiment, the winding section is connected to the first linear section and the second linear section through via holes, and the via holes are located at a junction portion the display area and the package area.

In an embodiment, the display area includes a pixel light-emitting area and a transition area, the transition area is disposed between the pixel light-emitting area and the package area, and the via holes are located in the transition area.

In an embodiment, the winding section is disposed at a position in the display area adjacent to the package area; in the display area, the display panel further includes a plurality of pixel units; and a number of winding sections of the winding lines in a single one of the pixel units adjacent to the package area is one, two, three, or four.

In an embodiment, the winding section is disposed at a position in the display area adjacent to the package area; in the display area, the display panel further includes a plurality of pixel units; a number of first connecting lines of the winding lines in a single one of the pixel units adjacent to the package area is one, two, three, or four; and a number of second connecting lines of the winding lines in the single one of the pixel units adjacent to the package area is one, two, three, or four.

In an embodiment, a number of the first connecting lines in the single one of the pixel units adjacent to the package area is one, and a number of the second connecting lines in the single one of the pixel units adjacent to the package area is two.

In an embodiment, the display panel further includes normal data lines and normal scan lines, the normal data lines are disposed in the second metal layer, and the normal scan lines are disposed in a same layer as the gates in the driving circuit layer; the winding lines includes one or more winding data lines, or one or more winding scan lines, or one or more of the winding data lines and one or more of the winding scan lines; and the first linear section and the second linear section of each of the winding data lines are disposed in a same layer as the normal data lines, and the first linear section and the second linear section of each of the winding scan lines are disposed in a same layer as the normal scan lines.

In an embodiment, the display panel includes one or more of the winding data lines and one or more of the winding scan lines; an area where the winding section of each of the winding scan lines is located is disposed on a side of an area where the winding section of each of the winding data lines adjacent to the package area.

In an embodiment, the display panel further includes: an inorganic layer disposed on a side of the substrate and at least in the package area; and a package base disposed on a side of the inorganic layer away from the substrate, in the package area, and around the functional area; herein, the package base is made of metal and provided with a plurality of grooves running through the package base and surrounding the functional area in turn; the plurality of grooves divides the package base into a plurality of humps, and each of the humps defines an undercut structure at one of the grooves.

In an embodiment, the package base is a Ti—Al—Ti lamination structure, each of the grooves runs through the Ti—Al—Ti lamination structure in a stacking direction of the Ti—Al—Ti lamination structure to divide the Ti—Al—Ti lamination structure into a plurality of Ti—Al—Ti humps, and an Al layer of each of the Ti—Al—Ti humps shrinks inwardly at one of the grooves and relative to an Ti layer away from the substrate to form the undercut structure.

In an embodiment, the package base further includes a cushion layer disposed between the inorganic layer and the Ti—Al—Ti lamination structure, and a material of the cushion layer is different from a material of the Ti—Al—Ti lamination structure.

In a second aspect, the present disclosure provides a display device, including a housing and the aforementioned display panel, and the display panel is accommodated in the housing.

### BENEFICIAL EFFECTS

### Beneficial Effects of the Present Disclosure:

In the present disclosure, the winding lines are arranged in the display area to narrow a border width of the functional area. At the same time, the present disclosure makes the winding sections correspond to other metal layers. In this way, in a visible viewing angle of the display panel, even though the winding sections are arranged in the display area, it will not cause differences of a patterned structure of the metal layer in the display area in a position close to the functional area and in a position away from the functional area, which can effectively relieve the mura display caused by the arrangement of the winding sections in the display area in the related art.

Furthermore, in the present disclosure, the winding sections are arranged corresponding to the reset signal line and the power signal line. The reset signal line and the power signal line are both connected with a constant signal, so an interference of the winding section to other signals can be reduced.

Furthermore, in the present disclosure, the pixel definition layer includes two stacked layers, and the first pixel definition layer is a black pixel definition layer, so as to further relieve the mura display.

Furthermore, in the present disclosure, the packaging bases made of metal material are arranged on the inorganic layer, a groove is provided on the packaging base, and an undercut structure is defined at the groove, so that when the light-emitting device is subsequently prepared, an evaporated organic functional layer will be disconnected at the undercut structures, thereby preventing water and oxygen from entering the display area along the organic functional layer from the functional area. Compared with that the packaging materials in the related art are in direct contact with the organic matter, the packaging material of the present disclosure is in direct contact with the inorganic matter and metal materials, which can prevent the water and oxygen in organic matter from entering and improve the water and oxygen resistance of the package structure, thereby effectively improving an encapsulation effect to relieve a phenomenon that black rings are easy to appear around the digging-hole when water and oxygen enter.

Furthermore, in the present application, the cushion layer is provided between the inorganic layer and the metal lamination structure, so a thickness of the package base can be effectively increased, that is, a thickness of the hump can be increased. Because the encapsulation effect of the package structure is also related to a length of an entering path of the water and oxygen, when the thickness of the hump increases, a number of the humps can be appropriately reduced without affecting the encapsulation effect. Therefore, a width of the package area is reduced to achieve the purpose of narrowing the border width of the functional area.

### DESCRIPTION OF DRAWINGS

In order to more clearly illustrate the technical solutions in the embodiments of the present disclosure, the drawings that need to be used in the description of the embodiments will be briefly introduced below. Obviously, the drawings in the following description are only some embodiments of the present disclosure. For those skilled in the art, other drawings can also be obtained based on these drawings without any creative effort.

FIG. 1 is a schematic top view of a display panel according to an embodiment of the present disclosure.

FIG. 2 is a schematic view of a sectional structure of the display panel along a line A-A in FIG. 1

FIG. 3 is a schematic view of a film structure of the display panel in a display area in FIG. 2.

FIG. 4 is a schematic plane view of a winding line of the display panel in FIG. 3.

FIG. 5 is another schematic plane view of a winding line of the display panel in FIG. 3.

FIG. 6 is a schematic plane view of the winding line and a reset signal line of the display panel in FIG. 3.

FIG. 7 is a schematic plane view of a package area of the display panel in FIG. 3.

### REFERENCE NUMERALS

display panel, 100; functional area, 101; package area, 102; first package area, 1021; second package area, 1022; display area, 103; pixel light-emitting area, 1031; transition area, 1032;
substrate, 10; first substrate, 11; second substrate, 12;
inorganic layer, 20;
first film lamination, 30; first gate insulation layer, 31; second gate insulation layer, 32; first interlayer insulation layer, 33; third gate insulation layer, 34; second interlayer insulation layer, 35;
second film lamination, 40; via hole, 401; first planarization layer, 41; insulation layer, 42; second planarization layer, 43;
package base, 50; groove, 501; hump, 502; undercut structure, 503; metal lamination structure, 51; cushion layer, 52;
dam, 60;
light-emitting device, 70; anode layer, 701; pixel definition layer, 702; pixel opening, 7020; first pixel definition layer, 7021; second pixel definition layer, 7022; anode, 71; light-emitting structure, 72;
data line, 80; normal data line, 81; winding data line, 82; first linear section, 821; second linear section, 822; winding section, 823; first connecting line, 8231; second connecting line, 8232;
thin film transistor, 90; semiconductor, 91; channel area, 911; source area, 912; drain area, 913; gate, 92; source, 93; drain, 94;
first thin film transistor, T1; second thin film transistor, T2; third thin film transistor, T3;
first active layer, 901; second active layer, 902; first gate layer, 903; second gate layer, 904; third gate layer, 905; source and drain layer, 906; first metal layer, 907; second metal layer, 908; power signal line, 9081; reset signal line, 909.

### EMBODIMENTS OF THE INVENTION

The technical solutions in the embodiments of the present disclosure will be clearly and completely described with reference to the accompanying drawings in the embodiments of the present disclosure. Obviously, the described embodiments merely indicate a part of the embodiments of the present disclosure, but not all the embodiments. Based on the embodiments in the present disclosure, all other embodiments obtained by those skilled in the art without creative work fall into the protection scope of the present disclosure. In addition, it should be understood that the specific embodiments described herein are intended only to illustrate and explain the present disclosure and are not intended to restrict it. In the present disclosure, where the contrary is not stated, the orientational terms “up/on” and “below/down” used generally refer to the up and down of the device in actual use or working condition, specifically refer to the directions of the surface in the attached drawings. The terms “inside/inner” and “outside/outer” refer to the outline of the device.

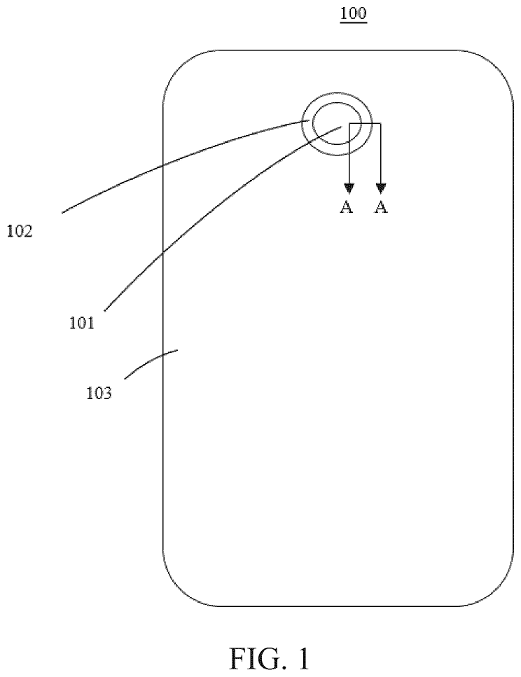

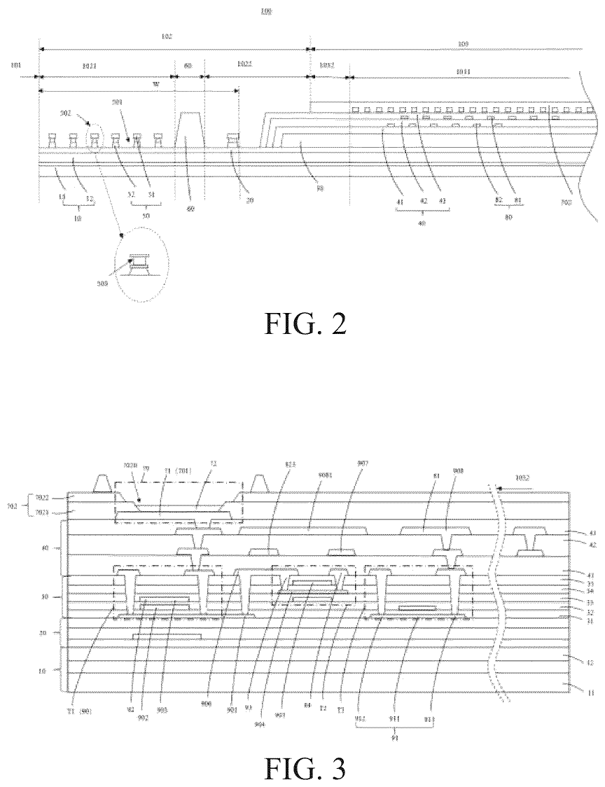

Referring to FIG. 1 and FIG. 2, a display panel 100 is provided according to the present disclosure. The display panel 100 includes a functional area 101, a package area 102 around the functional area 101, and a display area 103 around the functional area 101. The display area 103 is configured to display images. The functional area 101 may be arranged in a position of the display panel 100, for example, the functional area 101 may be arranged in a middle area or a border area of the display panel 100. The functional area 101 is provided with a through hole passing through film layers of the display panel 100, and a function component such as an earpiece, a camera, or a sensor can be placed in the through hole to realize function such as under-screen camera or under-screen fingerprint, thereby improving the screen-to-body ratio of the display panel 100. The package area 102 is located between the functional area 101 and the display area 103, and is mainly configured to arrange a package structure, so as to avoid affecting the encapsulation effect of the display panel 100 due to setting of the functional area 101.

The display panel 100 further includes a substrate 10, an inorganic layer 20 disposed on a side of the substrate 10, a first film lamination 30 disposed on a side of the inorganic layer 20 away from the substrate 10, a driving circuit layer disposed in the first film lamination 30, a second film lamination 40 disposed on a side of the first film lamination 30 away from the substrate 10, and a package base 50 disposed on a side of the inorganic layer 20 away from the substrate 10.

Optionally, the substrate 10 may be a rigid substrate or a flexible substrate. When the substrate 10 is a rigid substrate, it may be a glass substrate, and when the substrate 10 is a flexible substrate, it may be a polyimide (PI) film, an ultra-thin glass film, or other flexible substrate. When a flexible substrate is applied as the substrate 10, a flexible display panel can be formed to achieve special properties of the display panel 100, such as bending and rolling. In the embodiment, the substrate 10 is the polyimide film, and includes a first substrate 11 and a second substrate 12 stacked on the first substrate 11.

The inorganic layer 20 covers the substrate 10. Specifically, the inorganic layer 20 covers the second substrate 12. A material of the inorganic layer 20 may include an inorganic material such as silicon oxide (SiOx), silicon nitride (SiNx), silicon oxynitride (SiON), and so on. The inorganic layer 20 can further prevent unwanted impurities or contaminants (such as moisture, oxygen, etc.) from diffusing from the substrate 10 to devices inside the display panel 100, while also provide a flat top surface.

The first film lamination 30 and the second film lamination 40 are located in the display area 103 and extend from the display area 103 to part of the package area 102. In the embodiment, the first film lamination 30 includes an insulation layer stacked on the inorganic layer 20, and a number of layers of the insulation layer and functions of the layers can be changed according to the metal film layers in the display area and actual needs, that is, a structure of the first film lamination 30 is designed according to a specific structure and requirements of the driving circuit layer, which will be introduced later in detail. The second film lamination 40 includes a planarization layer stacked on the insulation layer. Similarly, a number of layers of the planarization layer and functions of the layers can be changed according to the metal film layers in the display area and actual needs, which will be introduced later in detail.

The display panel 100 includes at least one winding line arranged in the display area 103. The winding line includes a first linear section and a second linear section extending along a same direction and separated by the functional area 101 and the package area 102, and includes a winding section connecting the first linear section and the second linear section. The first linear section and the second linear section are arranged in a same layer. The winding section and the first linear section are arranged in different layers. A projection of the winding section in a thickness direction of the display panel is within a projection of other metal layers of the display panel 100 in the thickness direction of the display panel 100, and the other metal layers are arranged in different layers than the winding section.

The winding line may be a winding data line or a winding scan line. Or the winding lines may include the winding data line and the winding scan line. Herein, the first linear section and the second linear section of the winding data line are in same layer with a normal data line, and the first linear section and the second linear section of the winding scan line are in same layer with a normal scan line.

In order to clarify the description, in the embodiment, the winding line is described as a winding data line, and specifically, the film structure of the display panel 100 in the display area 103 is mainly described.

Referring to FIG. 3 to FIG. 6, in the embodiment, in the display area 103, the display panel 100 further includes a first metal layer 907 and a second metal layer 908 disposed on a side of the first metal layer 907 away from the substrate 10. The display panel 100 further includes a plurality of data lines 80 and a reset signal line 909 disposed on a side of the substrate 10, and the reset signal line 909 is a reset signal line in the aforementioned driving circuit layer. The plurality of data lines 80 include a plurality of normal data lines 81 and at least one winding data line 82, and the normal data lines 81 and the winding data line 82 are arranged in the display area 103. The winding data line 82 includes a first linear section 821 and a second linear section 822 extending in a same direction and separated by the package area 102, and includes a winding section 823 connecting the first linear section 821 and the second linear section 822. An extending direction of the normal data line 81 is same with the extending direction of the first linear section 821 and the second linear section 822. The normal data line 81, the first linear section 821, and the second linear section 822 are arranged in the second metal layer 908, and the winding section 823 is arranged in the first metal layer 907 and located at a position of the display area 103 close to the package area 102. An orthographic projection of the winding section 823 on the substrate 10 falls within orthographic projections of the second metal layer 908 and the reset signal line 909 on the substrate 10.

Specifically, in the embodiment, the reset signal line 909 is arranged between the inorganic layer 20 and the second film lamination 40, the first metal layer 907 and the second metal layer 908 are arranged inside the second film lamination 40.

In the embodiment, the purpose of narrowing the border width of the functional area 101 is realized by arranging the winding section 823 of the winding data line 82 of the data lines 80 in the display area 103. At the same time, the orthographic projection of the winding section 823 on the substrate 10 falls within the orthographic projections of the second metal layer 908 and the reset signal line 909 on the substrate 10, so in the visible viewing angle of the display panel 100, even though the winding section 823 is arranged in the display area 103, it will not cause differences of the patterned structure of the metal layer in the display area 103 where the data lines 81 is located in a position close to the functional area 101 and in a position away from the functional area 101, which can effectively relieve the mura display caused by the arrangement of the winding section 823 in the display area 103 in the related art.

In an embodiment, a connection point of the winding section 823 and the first linear section 821 and a connection point of the winding section 823 and the second linear section 822 are located at a junction portion of the display area 103 and the package area 102. Specifically, in the display area 103, an insulation layer is provided between the first metal layer 907 and the second metal layer 908. Via holes 401 are provided on the insulation layer, and the via holes 401 are located at the junction portion of the display area 103 and the package area 102. The winding section 823 is connected to the first linear section 821 and the second linear section 822 through the via holes 401.

Specifically, in the embodiment, the display area 103 includes a pixel light-emitting area 1031 and a transition area 1032. The transition area 1032 is located between the pixel light-emitting area 1031 and the package area 102. The pixel light-emitting area 1031 refers to an area where a light-emitting structure in the display area 103 is located, and a structure in the transition area 1032 is configured to transit the package structure in the package area 102 and a structure in the pixel light-emitting area 1031. It can be understood that a width of the transition area 1032 is very small, which can basically be equivalent to the junction portion of the display area 103 and the package area 102.

Optionally, the connection point of the winding section 823 and the first linear section 821 and the connection point of the winding section 823 and the second linear section 822 are located in the transition area 1032. That is, the via hole 401 is located in the transition area 1032, as shown in FIG. 5. It can be understood that, in other embodiments, the via hole 401 may also be arranged in the pixel light-emitting area 1031.

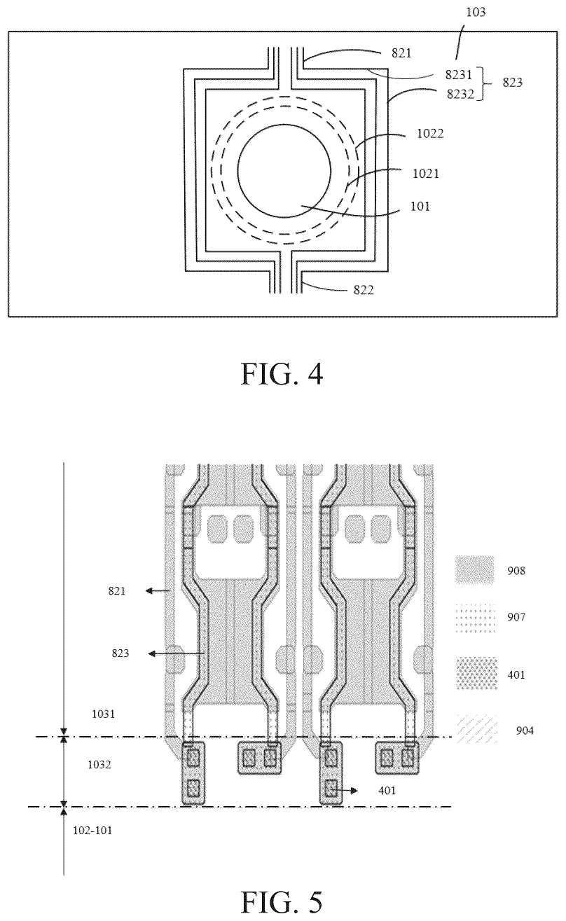

Optionally, the winding section 823 includes at least one first connecting line 8231 extending along a first direction and at least one second connecting line 8232 extending along a second direction. Two ends of the first connecting line 8231 and the second connecting line 8232 after connected in a head-to-tail way are connected to the first linear section 821 and the second linear section 822, respectively. Specifically, referring to FIG. 4 to FIG. 6, in the embodiment, the winding section 823 includes two first connecting lines 8231 extending along the first direction and one second connecting line 8232 extending along the second direction. The two the first connecting line 8231 are connected to the first linear section 821 and the second linear section 822, respectively, and the second connecting line 8232 connects the two first connecting line 8231. An orthographic projection of the first connecting line 8231 on the substrate 10 falls within an orthographic projection of the reset signal line 909 on the substrate 10, and an orthographic projection of the second connecting line 8232 on the substrate 10 falls within an orthographic projection of the second metal layer 908 on the substrate 10.

In the embodiment, in view of an operation state of the display panel 100, the first direction is a horizontal, and the second direction is longitudinal. That is, a horizontal portion of the winding section 823 is disposed directly above the reset signal line 909, and a longitudinal portion of the winding section 823 is hidden under the second metal layer 908.

Since the horizontal portion of the reset signal line 909 is designed to be fixed, it is only necessary to arrange the winding section 823 accordingly. At the same time, because the reset signal line 909 is connected to a constant signal, when the first connecting line 8231 is arranged directly above the reset signal line 909, its interference to other signals can be reduced.

Optionally, the second metal layer 908 further includes a power signal line 9081, and an orthographic projection of the second connecting line 8232 on the substrate 10 falls within an orthographic projection of the power signal line 9081 on the substrate 10. Since the power signal line 9081 is connected to a constant signal, when the second connecting line 8232 is hidden under the power signal line 9081, its interference to other signals can be reduced.

Furthermore, in the display area 103, the display panel 100 further includes a plurality of pixel units arranged in an array. The winding section 823 is disposed at a portion in the display area 103 adjacent to the package area 102. A number of the winding sections 823 in a single pixel unit adjacent to the package area 102 may be one, two, three, or four. Specifically, a number of the first connecting lines 8231 in a single pixel unit adjacent to the package area 102 may be one, two, three, or four; and a number of the second connecting line 8232 in a single pixel unit adjacent to the package area 102 may be one, two, three, or four.

It can be understood that the number of the winding section 823 in the single pixel unit can be changed according to actual design requirements. When a planar space of the display area 103 around the functional area 101 is large enough, it is a preferred solution to arrange one of the winding sections 823 in one single pixel unit, so as to reduce the interference of the winding sections 823 to other signals. When the planar space of the display area 103 around the functional area 101 is limited, it is a preferred solution to arrange at least two of the winding sections 823 in one single pixel unit, so as to meet the functional design first. That is, an area of the display area 103 for arranging the winding sections 823 can be designed and changed according to the actual situation.

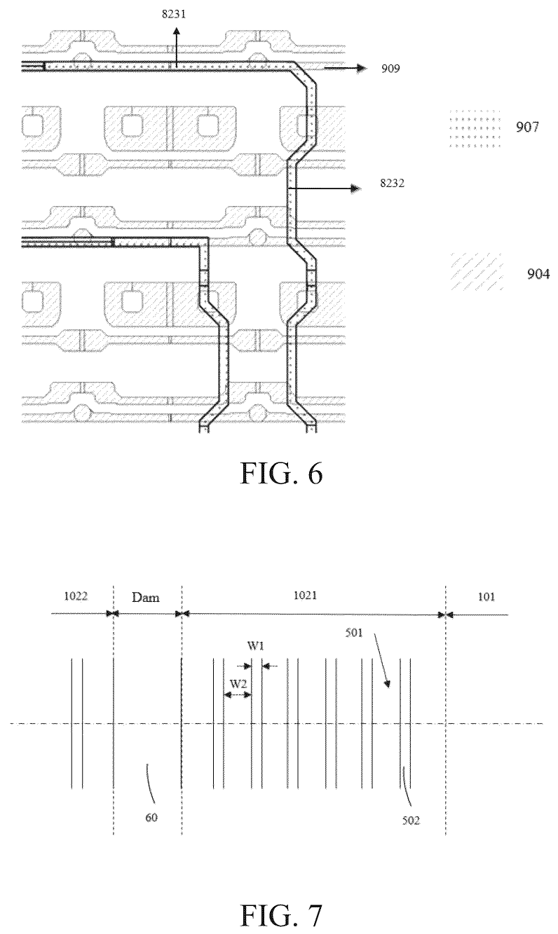

Specifically, in the embodiment, the number of the first connecting line 8231 in the single pixel unit adjacent to the package area 102 is one, and the number of the second connecting lines 8232 in the single pixel unit adjacent to the package area 102 is two, as shown in FIG. 5 and FIG. 6.

Furthermore, in the embodiment, in the display area 103, the display panel 100 further includes a plurality of thin film transistors 90 disposed on the inorganic layer 20 and a plurality of light-emitting devices 70 disposed on the second film lamination 40. A film layer structure of the plurality of thin film transistors 90 together constitutes the driving circuit layer.

Each thin film transistor 90 includes a semiconductor 91, a gate 92, a source 93, and a drain 94. The semiconductor 91 includes a channel area 911, and a source area 912 and a drain area 913 located on two sides of the channel area 911. In a same thin film transistor 90, the gate 92 corresponds to the channel area 911, the source 93 is electrically connected to the source area 912, and the drain is electrically connected to the drain area 913.

It can be understood that types and functions of the thin film transistors 90 can be designed differently according to actual requirements. For example, in the embodiment, the plurality of thin film transistors 90 at least include a first thin film transistor T1, a second thin film transistor T2, and a third thin film transistor T3. Herein, the first thin film transistor T1 adopts a structure including double top gates and is electrically connected to the light-emitting device 70. The second thin film transistor T2 adopts structure including a top gate and a bottom gate, and the source of the second thin film transistor T2 is electrically connected to the drain of the first thin film transistor T1. The third thin film transistor T3 adopts a structure including a single top gate is electrically connected to the data line.

In order to arrange the thin film transistors 90 described above, in the embodiment, the driving circuit layer of the display panel 100 includes a first active layer 901, a second active layer 902, a first gate layer 903, a second gate layer 904, a third gate layer 905, and a source and drain layer 906. Specifically, the first active layer 901 is disposed on the inorganic layer 20. The semiconductor of the first thin film transistor T1 and the semiconductor of the third thin film transistor T3 are both disposed on the first active layer 901. The first gate layer 903 and the second gate layer 904 are sequentially disposed on a side of the first active layer 901 away from the inorganic layer 20, and a first gate and a second gate of the first thin film transistor T1 are respectively located in the first gate layer 903 and the second gate layer 904. A bottom gate of the second thin film transistor T2 is located in the second gate layer 904. A top gate of the the third thin film transistor T3 is located in the first gate layer 903. The second active layer 902 is disposed on a side of the second gate layer 904 away from the inorganic layer 20. The semiconductor of the second thin film transistor T2 is located on the second active layer 902. The third gate layer 905 is disposed on a side of the second active layer 902 away from the inorganic layer 20. A top gate of the second thin film transistor T2 is located in the third gate layer 905. The source and drain layer 906 is disposed on a side of the third gate layer 905 away from the inorganic layer 20, the source and the drain of the first thin-film transistor T1, the source and the drain of the second thin-film transistor T2, and the source and the drain of the third thin film transistor T3 are located in the source and drain layer 906.

A film layer structure of the first film lamination 30 is set correspondingly according to the film layer structure of the plurality of thin film transistors 90, that is, according to the aforementioned driving circuit layer. In order to correspond to the structure of the thin film transistors 90 described above, in the embodiment, the first film lamination 30 includes a first gate insulation layer 31, a second gate insulation layer 32, a first interlayer insulation layer 33, a third gate insulation layer 34, and a second interlayer insulation layer 35 sequentially stacked on the inorganic layer 20. Specifically, the first gate insulation layer 31 is disposed on the inorganic layer 20 and separates the first gate layer 903 from the first active layer 901. The second gate insulation layer 32 is disposed on the first gate insulation layer 31 and separates the second gate layer 904 from the first gate layer 903. The first interlayer insulation layer 33 is disposed on the second gate insulation layer 32 and separates the second active layer 902 from the second gate layer 904. The third gate insulation layer 34 is disposed on the first interlayer insulation layer 33 and separates the third gate layer 905 from the second active layer 902; the second interlayer insulation layer 35 is disposed on the third gate insulation layer 34 and separates the source and drain layer 906 from the third gate layer 905.

In order to correspond to the structure of the data lines 80, in the embodiment, the second film lamination 40 includes a first planarization layer 41, an insulation layer 42, and a second planarization layer 43. Specifically, the first planarization layer 41 is disposed on a side of the second interlayer insulation layer 35 of the first film lamination 30 away from the substrate 10 and separates the first metal layer 907 from the source and drain layer 906. The insulation layer 42 is disposed on a side of the first planarization layer 41 away from the substrate 10 and separates the second metal layer 908 from the first metal layer 907. The second planarization layer 43 is disposed on a side of the insulation layer 42 away from the substrate 10 and covers the second metal layer 908. The insulation layer 42 may be organic or inorganic, and the via hole 401 runs through the insulation layer 42.

Each light-emitting device 70 includes an anode 71, a light-emitting structure 72, and a cathode (not shown). The anode 71 is electrically connected to the corresponding first thin film transistor T1, and the light-emitting structure 72 is disposed on the corresponding anode 71. Specifically, the display panel 100 includes an anode layer 701 and a pixel definition layer 702. The anode layer 701 is disposed on a side of the second planarization layer 43 of the second film lamination 40 away from the substrate 10. The pixel definition layer 702 is disposed on a side of the second planarization layer 43 and a side of the anode layer 701 away from the substrate 10. A plurality of pixel openings 7020 are defined on the pixel definition layer 702, and the light-emitting structure 72 is disposed in the corresponding pixel opening 7020.

Optionally, in the embodiment, the pixel definition layer 702 includes a first pixel definition layer 7021 and a second pixel definition layer 7022 stacked on the first pixel definition layer 7021. The first pixel definition layer 7021 is disposed between the second pixel definition layer 7022 and the second planarization layer 43, and the first pixel definition layer 7021 is black, so as to further relieve mura display.

In order to protect the light emitting device 70 to prevent the light emitting device 70 from failing due to water and oxygen, the display panel 100 further includes a package layer (not shown), and the package layer covers the light emitting device 70. The package layer may be a thin film, for example, the package layer may be a film lamination structure formed by sequentially stacking three thin films of a first inorganic package layer, an organic package layer, and a second inorganic package layer, or a film lamination structure of more layers. A material of the organic package layer includes one or more of organic materials such as epoxy series and acrylic series, and the organic package layer may be coated on the first inorganic package layer through one of the ink jet printing (IJP), spraying, and other coating processes.

Furthermore, in the embodiment, according to functional division, the reset signal line 909 includes a first reset signal line and a second reset signal line. The first reset signal line is electrically connected to the gate of a driving thin film transistor, and is configured to reset a potential of the gate of the driving thin film transistor. The second reset signal line is electrically connected to the anode of the light emitting device, and is configured to reset a potential of the anode of the light emitting device.

Specifically, in the embodiment, the first reset signal line is arranged in a same layer with the top gate of the driving thin film transistor (that is, the first thin film transistor T1), and the second reset signal line is arranged in a same layer with the source and drain layer 906. In the embodiment, the orthographic projection of the first connecting line 8231 on the substrate 10 falls within n orthographic projection of the first reset signal line on the substrate 10.

Furthermore, In the embodiment, the first metal layer 907 further includes first lines connecting the thin film transistor 90 and the light-emitting devices 70 and second lines connecting the thin film transistor 90 and the data lines.

It can be understood that, in other embodiments, when the winding line is a winding scan line, an arrangement of the winding section of the winding scan line can be basically same as that of the winding section 823 of the winding data line 82, except that at: firstly, the first linear section and the second linear section of the winding scan line and the normal scan lines are arranged in a same layer with the gate of the thin film transistor, for example, the normal scan lines may be arranged in the aforementioned first gate layer 903 and third gate layer 905; secondly, because the extending direction of the normal scan line and the normal data line are perpendicular, the winding section of the winding scan line includes one first connecting line extending along the first direction and two second connecting lines extending along the second direction, the two second connecting lines are respectively connected to the first linear section and the second linear section, and the first connecting line connects the two second connecting lines.

It can be understood that, in other embodiments, the winding lines may include the aforementioned winding data line 82 and the winding scan line at the same time. When the winding lines includes the winding data line 82 and the winding scan line at the same time, the winding section of the winding scan line and the winding section of the winding data line can be arranged in partitions, and they do not overlap or be staggered with each other. Specifically, an area where the winding section of the winding scan line is located may be located on a side of an area where the winding section 823 of the winding data line is located adjacent to the package area 102.

In addition, in the related art, a frame package of the hole-digging area is formed by depositing package materials on the package base, and the package base is an undercut structure formed by etching the substrate and the inorganic layer on the substrate. Since the substrate generally is a flexible substrate such as an PI film or an ultra-thin glass film, the package material of the package structure is directly in contact with organic matter, the water and oxygen resistance is insufficient, and black rings are easy to appear around the digging-hole when water and oxygen enter. Therefore, in order to improve the water and oxygen resistance performance of the frame package of the hole-digging area of the display device in related art, the present disclosure further designs the package area 102 of the display panel 100 on the basis of the foregoing.

The film layer structure of the display panel 100 in the package area 102 will be described in detail below.

Referring to FIG. 2 and FIG. 7, the package base 50 is located in the package area. Specifically, in the package area, the package base 50 is provided with a plurality of grooves 501 surrounding the functional area 101 in turn. Each groove 501 runs through the package base 50, and the plurality of grooves 501 divides the package base 50 into a plurality of humps 502. Each hump 502 defines an undercut structure 503 at the groove 501.

In the present disclosure, the package substrate 50 made of metal is provided on the inorganic layer 20, grooves 501 are provided on the package substrate 50, and an undercut structure 503 is formed at the groove 501, so when the light-emitting device is subsequently prepared, an evaporated organic functional layer will be disconnected at the undercut structures 503, thereby preventing water and oxygen from entering the display area 103 from the functional area 101 along the organic functional layer. At the same time, when encapsulating material (not shown) is subsequently deposited to realize the encapsulation of the functional area 101, compared with the related art in which the encapsulating material directly contacts the organic matter, the encapsulating material of the present disclosure directly contacts the inorganic matter and the metal materials, so the intrusion of water and oxygen in the organic matter can be avoided, which improves the anti-water and oxygen performance of the package structure, thereby effectively improving the encapsulation effect, and relieving the phenomenon that black rings are prone to appear around the digging-hole after water and oxygen enters.

Specifically, it has been proved by experiments that when a display device (such as a mobile phone) applying the package structure in the related art is placed under a conditions of a temperature of 85° C. and a humidity of 85% when it is not working, black rings (that is, the hole black ring phenomenon) will appear at the surrounding of the functional area 101 after about 120 hours, and the display device applying the package structure of the present disclosure can effectively improve the encapsulation effect and avoid the phenomenon of black rings.

Optionally, in the embodiment, the package substrate 50 includes a metal lamination structure 51, and the metal lamination structure 51 is a Ti—Al—Ti lamination structure. Each groove 501 runs through the Ti—Al—Ti lamination structure in a stacking direction of the Ti—Al—Ti lamination structure to divide the Ti—Al—Ti lamination structure into a plurality of Ti—Al—Ti humps. An Al layer of each Ti—Al—Ti hump shrinks inwardly at the groove 501 and relative to an Ti layer away from the substrate 10 to form the undercut structure 503. The metal lamination structure 51 can be obtained by same manufacturing process with one or some metal layers in the display area 103 to simplify the manufacturing process. Specifically, in the embodiment, the metal lamination structure 51 and the second metal layer 908 are made of a same material and obtained by a same manufacturing process.

Optionally, the package base 50 further includes a cushion layer 52 disposed between the inorganic layer 20 and the metal lamination structure 51. A material of the cushion layer 52 is different from that of the metal lamination structure 51. The cushion layer 52 can be obtained through a same manufacturing process with one or some metal layers in the display area 103 to simplify the manufacturing process. Specifically, in the embodiment, the cushion layer 52 and the gate layer of one of the thin film transistors are made of a same material and obtained through a same process. Specifically, in the embodiment, the process of the cushion layer 52 is same as that of the first gate layer 903 and the second gate layer 904.

In the present disclosure, by adding the cushion layer 52 between the inorganic layer 20 and the metal lamination structure 51, the thickness of the package substrate 50 can be effectively increased, that is, the thickness of the hump 502 can be increased. Because the encapsulation effect of the package structure is also related to the length of the intrusion path of the water and oxygen, when the thickness of the hump 502 increases, the number of the humps 502 can be appropriately reduced without affecting the encapsulation effect, and then the width of the package area can be appropriately reduced to achieve the purpose of narrowing the border width of the functional area 101.

Experiments have proved that in order to ensure the encapsulation effect, when using the package substrate in the related art, the width (a distance from the first hump close to the display area to the hole-digging area) of the package substrate needs to be about 265 um. However, when the package substrate 50 of the present disclosure is applied, the width W of the package substrate 50 only needs to be 221 um, which can effectively narrow the border width of the functional area 101.

Specifically, in the embodiment, the package area includes t a first package area 1021 surrounding the functional area 101 and a second package area 1022 enclosing the first package area 1021. A dam 60 is provided between the second package area 1022 and the first package area 1021. That is, the dam 60 is arranged around the functional area 101, so as to define the first package area 1021 between the dam 60 and the functional area, and to define the second package area 1022 between the dam 60 and the display area 103. The dam 60 is configured to assist in completing the fabrication of the package structure in the first package area 1021 and the second package area 1022. In the embodiment, there are six humps 502 in the first package area 1021, and the width W1 of each hump 502 in the first package area 1021 is 5 microns, a width W2 of each groove 501 is 15 microns, and there is one hump 502 disposed in the second package area 1022.

Based on the same idea, the present disclosure further provides a display device including a housing (not shown) and the display panel 100 of the foregoing embodiment. The housing is provided with an accommodating cavity, and the display panel 100 is assembled in the accommodating cavity. The display device can be a wearable device, such as a smart bracelet, a smart watch, or a virtual reality (VR) device, or a mobile phone, an e-book, an e-newspaper, a TV set, or a personal portable computer. It may be a bendable and foldable flexible OLED display or lighting device, and the embodiment of the present disclosure does not specifically limit the specific form of the electronic device.

In summary, although the present disclosure has disclosed the above with preferred embodiments, it is understandable that various embodiments can be combined in any way, but the above preferred embodiments are not intended to limit the present disclosure. Various modifications and modifications can be made without departing from the spirit and scope of the present disclosure, so the protection scope of the present disclosure is subject to the scope defined by the claims.

1. A display panel, comprising a functional area, a package area around the functional area, a display area around the functional area, and comprising one or more winding lines disposed in the display area,
wherein each of the winding lines comprises a first linear section and a second linear section extending along a same direction and separated by the functional area and the package area, and comprises a winding section connecting the first linear section and the second linear section;
the first linear section and the second linear section are arranged in a same layer, and the winding section and the first linear section are arranged in different layers; and
a projection of the winding section in a thickness direction of the display panel falls within a projection of other metal layers of the display panel in the thickness direction of the display panel.

2. The display panel according to claim 1, further comprising:
a substrate;
a driving circuit layer disposed on a side of the substrate;
a first metal layer disposed on a side of the driving circuit layer away from the substrate; and
a second metal layer disposed on a side of the first metal layer away from the substrate,
wherein the winding section is disposed in the first metal layer, and an orthographic projection of the winding section on the substrate falls within an orthographic projection of the driving circuit layer and an orthographic projection of the second metal layer on the substrate.

3. The display panel according to claim 2, wherein the winding section comprises at least one first connecting line extending along a first direction and at least one second connecting line extending along a second direction;
two ends of the first connecting line and the second connecting line after connected in a head-to-tail way are connected to the first linear section and the second linear section, respectively; and
an orthographic projection of the first connecting line on the substrate falls within an orthographic projection of the driving circuit layer on the substrate, and an orthographic projection of the second connecting line on the substrate falls within an orthographic projection of the second metal layer on the substrate.

4. The display panel according to claim 3, further comprising a reset signal line, wherein the reset signal line is disposed in the driving circuit layer, and an orthographic projection of the first connecting line on the substrate falls within an orthographic projection of the reset signal line on the substrate.

5. The display panel according to claim 4, further comprising a power signal line, wherein the power signal line is disposed in the second metal layer, and an orthographic projection of the second connecting line on the substrate falls within an orthographic projection of the power signal line on the substrate.

6. The display panel according to claim 4, wherein the reset signal line comprises a first reset signal line and a second reset signal line;
in the display area, the display panel further comprises a plurality of light-emitting devices and a plurality of driving thin film transistors disposed in the driving circuit layer; and
the first reset signal line is electrically connected to gates of the driving thin film transistors, and the second reset signal line is electrically connected to anodes of the light-emitting devices.

7. The display panel according to claim 6, wherein in the display area, the driving circuit layer comprises the gates and a source and drain layer of the driving thin film transistors; the first reset signal line and the gates of the driving thin film transistors are disposed in a same layer; and the second reset signal line and the source and drain layer are disposed in a same layer.

8. The display panel according to claim 7, wherein an orthographic projection of the first connecting line on the substrate falls within an orthographic projection of the first reset signal line on the substrate.

9. The display panel according to claim 6, wherein in the display area, the display panel further comprises a pixel definition layer comprising a first pixel definition layer and a second pixel definition layer stacked thereon;
the first pixel definition layer is black and disposed on the anodes of the light-emitting devices, and the second pixel definition layer is disposed on a side of the first pixel definition layer away from the substrate;
a plurality of pixel openings, defined on the pixel definition layer, run through the second pixel definition layer and a part of the first pixel definition layer to expose the anodes; and
each of the light-emitting devices comprises a light-emitting structure disposed in one of the pixel openings and on one of the anodes correspondingly.

10. The display panel according to claim 1, wherein the winding section is connected to the first linear section and the second linear section through via holes, and the via holes are located at a junction portion the display area and the package area.

11. The display panel according to claim 10, wherein the display area comprises a pixel light-emitting area and a transition area, the transition area is disposed between the pixel light-emitting area and the package area, and the via holes are located in the transition area.

12. The display panel according to claim 1, wherein the winding section is disposed at a position in the display area adjacent to the package area;
in the display area, the display panel further comprises a plurality of pixel units; and
a number of winding sections of the winding lines in a single one of the pixel units adjacent to the package area is one, two, three, or four.

13. The display panel according to claim 3, wherein the winding section is disposed at a position in the display area adjacent to the package area;
in the display area, the display panel further comprises a plurality of pixel units;
a number of first connecting lines of the winding lines in a single one of the pixel units adjacent to the package area is one, two, three, or four; and
a number of second connecting lines of the winding lines in the single one of the pixel units adjacent to the package area is one, two, three, or four.

14. The display panel according to claim 13, wherein a number of the first connecting lines in the single one of the pixel units adjacent to the package area is one, and a number of the second connecting lines in the single one of the pixel units adjacent to the package area is two.

15. The display panel according to claim 2, further comprising normal data lines and normal scan lines, wherein the normal data lines are disposed in the second metal layer, and the normal scan lines are disposed in a same layer as the gates in the driving circuit layer;
the winding lines comprises one or more winding data lines, or one or more winding scan lines, or one or more of the winding data lines and one or more of the winding scan lines; and
the first linear section and the second linear section of each of the winding data lines are disposed in a same layer as the normal data lines, and the first linear section and the second linear section of each of the winding scan lines are disposed in a same layer as the normal scan lines.

16. The display panel according to claim 15, further comprising one or more of the winding data lines and one or more of the winding scan lines, wherein an area where the winding section of each of the winding scan lines is located is disposed on a side of an area where the winding section of each of the winding data lines adjacent to the package area.

17. The display panel according to claim 2, further comprising:
an inorganic layer disposed on a side of the substrate and at least in the package area; and
a package base disposed on a side of the inorganic layer away from the substrate, in the package area, and around the functional area,
wherein the package base is made of metal and provided with a plurality of grooves running through the package base and surrounding the functional area in turn;
the plurality of grooves divides the package base into a plurality of humps, and each of the humps defines an undercut structure at one of the grooves.

18. The display panel according to claim 17, wherein the package base is a Ti—Al—Ti lamination structure; each of the grooves runs through the Ti—Al—Ti lamination structure in a stacking direction of the Ti—Al—Ti lamination structure to divide the Ti—Al—Ti lamination structure into a plurality of Ti—Al—Ti humps, and an Al layer of each of the Ti—Al—Ti humps shrinks inwardly at one of the grooves and relative to an Ti layer away from the substrate to form the undercut structure.

19. The display panel according to claim 18, wherein the package base further comprises a cushion layer disposed between the inorganic layer and the Ti—Al—Ti lamination structure, and a material of the cushion layer is different from a material of the Ti—Al—Ti lamination structure.

20. A display device, comprising:
a housing; and
a display panel accommodated in the housing,
wherein the display panel comprises a functional area, a package area around the functional area, a display area around the functional area, and comprising one or more winding lines disposed in the display area;
each of the winding lines comprises a first linear section and a second linear section extending along a same direction and separated by the functional area and the package area, and comprises a winding section connecting the first linear section and the second linear section;
the first linear section and the second linear section are arranged in a same layer, and the winding section and the first linear section are arranged in different layers; and
a projection of the winding section in a thickness direction of the display panel falls within a projection of other metal layers of the display panel in the thickness direction of the display panel.
